(19) United States
(12) Patent Application Publication
(10) Pub. No.: US 2016/0273102 A1
(43) Pub. Date: Sep. 22, 2016

(54) TAPE-SUBSTRATE COATING LINE HAVING A MAGNETRON ARRANGEMENT

(71) Applicant: VON ARDENNE GmbH, Dresden (DE)

(72) Inventors: Holger PROEHL, Dresden (DE); Michael HENTSCHEL, Dresden (DE); Andreas DASSLER, Haenichen (DE); Christoph KAISER, Dresden (DE); Andreas MUELLER, Dresden (DE)

(21) Appl. No.: 15/066,772

(22) Filed: Mar. 10, 2016

(30) Foreign Application Priority Data
Mar. 18, 2015 (DE) 10 2015 104 039.5

(51) Int. Cl. C23C 16/455; C23C 16/52; C23C 16/44

(52) U.S. Cl. CPC C23C 16/455; C23C 16/4412; C23C 16/52

(57) ABSTRACT

A tape-substrate coating line has a vacuum chamber formed by chamber walls and a device, disposed in the vacuum chamber, for surface treatment of a tape substrate. The device includes a process temperature-control roller having a cylindrical lateral face. At least one part-circumference of the lateral face is enclosed by a processing space which has an arrangement of compartments delimited by separation wall elements. At least one coating installation is disposed in at least one compartment, and includes a conveying installation for conveying the tape substrate over the lateral face. The size, number and arrangement of the compartments are variable in that each separation wall element is attachable to one of a plurality of predefined positions within the processing space.

### CROSS REFERENCE TO RELATED APPLICATIONS

This application claims priority of German Application No. 10 2015 104 039.5 filed on Mar. 15, 2015, the entire contents of which is hereby incorporated by reference herein.

### BACKGROUND ART

The invention relates to a tape-substrate coating line having a vacuum chamber formed by chamber walls and a device, disposed in the vacuum chamber, for surface treatment of a tape substrate, and comprising a process temperature-control roller having a cylindrical lateral face, wherein at least one part-circumference of the lateral face is enclosed by a processing space which has an arrangement of compartments delimited by separation wall elements, wherein at least one coating installation is disposed in at least one compartment, and comprising a conveying installation for conveying the tape substrate over the lateral face.

Known tape-substrate coating lines having a device for surface-treating, in particular for coating a tape substrate, for example a metal or plastics tape/film tape, comprise an evacuatable vacuum chamber formed by chamber walls, a process temperature-control roller which is disposed therein and has a cylindrical lateral face for guiding the tape substrate in a temperature-controlled manner around a part-circumference of the lateral face, and an arrangement of compartments which are evacuatable by means of vacuum pumps and which are distributed across a part-circumference of the lateral face.

The tape substrate to be treated is guided by means of a conveying installation from a supply roll along the lateral face of the process temperature-control rollers and along the coating installations disposed in the evacuatable compartments to a take-up roll. The take-up roll and the supply roll here may either each be disposed so as to be in a dedicated and evacuatable reeling chamber, or else in the vacuum chamber. Between the supply roll and the take-up roll, the tape substrate is guided by a conveying installation, comprising inter alia deflection rollers, strip tension measurement rollers, so that said tape substrate is guided free of folds and creases along the lateral face of the process temperature-control roller. Moreover, it is known for the conveying direction of the tape substrate to be reversed between the supply roll and the take-up roll, for example so that the tape substrate may be treated once again, in particular coated once again, during conveying from the take-up roll to the supply roll.

By means of the process temperature-control roller the tape substrate per se and the coating material deposited on the tape substrate may be cooled and thus be protected from overheating, on the one hand, and by means of the process temperature-control roller the tape substrate may be heated so as to enable specific substrate treatments, on the other hand. The process temperature-control roller is configured so as to be rotatable about the central axis thereof by means of a drive which is disposed outside the vacuum chamber.

Various embodiments are known in terms of the arrangement of the compartments across a part-circumference of the lateral face of the process temperature-control roller.

WO 2014/060468 A1 discloses a tape-substrate coating line comprising a process temperature-control roller, wherein at least a part-circumference of the lateral face of the process temperature-control roller is enclosed by a processing space which has an arrangement of through compartments. The size of each of the compartments is identical and is dimensioned such that a device for surface treatment, in particular a coating installation, which is configured as a double magnetron tube, may be disposed in the interior of a compartment formed by wall elements. The wall elements are configured as mutually contacting sheet metal panels, for example, so that a volumetric flow from the vacuum chamber into the compartment is reduced to a minimum. In the case of a process temperature-control roller having a horizontally aligned rotation axis, compartments having the coating installations disposed therein are disposed so as to be mutually spaced apart in the 2 o'clock, 4 o'clock, 6 o'clock, 8 o'clock, and 10 o'clock positions, wherein, in an analogous manner to a clock face, the 6 o'clock position corresponds to the lowest point of the periphery of the process temperature-control roller. Furthermore, the compartments, together with the coating installation in each case disposed therein, are removable as two mutually separate part-assemblies from the vacuum chamber and replaceable therein through an opening in a chamber wall of the vacuum chamber, which is closable in a vacuum-tight manner. The interior of each compartment is evacuatable by way of one vacuum pump which is disposed outside the vacuum chamber.

In the case of this known tape-substrate coating line therefore the size, the number, as well as the arrangement of the compartments in terms of construction is predefined. One double magnetron tube, a single magnetron tube, a planar magnetron, a thermal evaporator having steam manifold tubes, an ion source, or another coating source may be disposed in each compartment, for example.

It is disadvantageous in the case of this construction that the size of each compartment is conceived and in terms of construction is fixedly predefined for the size of a double magnetron tube. In other words, the size of each compartment is dimensioned such that a double magnetron tube may be disposed therein, wherein the volume of the interior of the compartment is as small as possible so as to minimize the volume to be evacuated. If for another coating task the compartments are equipped with another coating installation, for example a single magnetron tube, for example in order to deposit another layer system on a tape substrate, it may be that these are smaller than a double magnetron tube. In this way, the part-circumference which is actually available around the lateral face is not completely utilized for coating the tape substrate. While two single magnetron tubes may indeed be disposed in one compartment, this is only possible when the processes carried out on both single magnetron tubes require the same process gas.

It is furthermore disadvantageous that the number and position of the compartments in terms of construction is predefined. If layer systems having a number of materials which is larger than the number of compartments are to be deposited on the tape substrate, or if the coating thickness to be deposited is to be increased, this is not readily possible by way of this known tape-substrate coating line. Rather, another tape-substrate coating line having a larger number of compartments for depositing this layer system would have to be used.

As opposed to this tape-substrate coating line, other tape-substrate coating lines in which the compartments are disposed in a locationally fixed manner in the vacuum chamber are known, with only the coating installations being removable from an opening in a chamber wall of the vacuum chamber, which is closable in a vacuum-tight manner. Also in the case of these devices for surface treatment the size, the number, as well as the arrangement of the compartments in terms of construction is fixedly predefined. It may be provided in the conveying direction of the tape substrate that one gas separation installation is disposed in each case between the compartments. On account of the compartments being disposed in a locationally fixed manner, the size, number, and arrangement of the gas separation installation is also fixedly predefined.

In U.S. Pat. No. 4,204,942 A, a cooling roller for conveying tape is surrounded by a plurality of coating units which are each isolated by gaps from the well evacuated vacuum chamber.

U.S. Pat. No. 4,692,233 A discloses a coating line for tape substrates, wherein the tape substrate is guided by means of a conveying installation along a coating roller and the surface of the tape substrate is treated. Here, a plurality of processing spaces (compartments) which are mutually separated by means of separation wall elements which are disposed at fixed positions are disposed along the cylindrical lateral face of the coating roller.

It is thus an object of the invention to state a tape-substrate coating line in which the number, the size, as well as the arrangement of the compartments is variable, in which comparatively large layer thicknesses are depositable, and in which flexibility in terms of the layer systems which are depositable on the tape substrate is increased.

### BRIEF SUMMARY OF THE INVENTION

In a tape-substrate coating line having a vacuum chamber formed by chamber walls and a device, disposed in the vacuum chamber, for surface treatment of a tape substrate, and comprising a process temperature-control roller having a cylindrical lateral face, wherein at least one part-circumference of the lateral face is enclosed by a processing space which has an arrangement of compartments delimited by separation wall elements, and wherein at least one coating installation is disposed in at least one compartment, and having a conveying installation for conveying the tape substrate over the lateral face, it is proposed that the size, number and arrangement of the compartments are variable in that the separation wall elements each are attachable to one of a plurality of predefined positions within the processing space.

The proposed solution in a tape-substrate coating line enables for the first time the processing region, which extends around a part-region of the process temperature-control roller, to be subdivided on demand into a greater or smaller number of compartments which each may be of dissimilar sizes, so that one and the same coating line is rapidly and simply adaptable to various processes for producing the most varied layer systems on tape substrates.

To this end, it is also no longer necessary for at least the so-called compartment arrangement to be replaced. Rather, an arrangement of separation wall elements having the desired configuration is inserted or push-fitted with the least possible outlay, on account of which any arbitrary arrangement of various functional compartments of arbitrary size is created. Functional compartments may be compartments for coating, etching, plasma treating, heating or cooling of the substrate, etc., for example.

Separation wall elements which are capable of subdividing the processing space into a plurality of compartments may be for example planar sheet metal panels which in relation to the process temperature-control roller extend radially and axially, that is to say parallel with the longitudinal axis thereof. Each such separation wall element forms the boundary between two mutually adjacent compartments. According to the invention, each such separation wall element may be attached at various positions, so that the position of the boundary between compartments may be modified in the simplest manner.

The fundamental concept of the invention lies in that the flexibility of the tape-substrate coating line in terms of the size, number and arrangement of the compartments is increased. As opposed to existing tape-substrate coating lines, this configuration of size, number, and arrangement of the compartments is freely selectable.

It is particularly advantageous that the position of the separation wall elements may also be modified post production of the tape-substrate coating line. For example, the separation wall elements may be attached to the predefined positions such that coating installations of the same type, for example sputtering installations having the same target material, are grouped together in one compartment. In this way it is possible for the compartment to be selected to be of such size that more than one double magnetron tube may be attachable as a coating installation in this compartment, for example.

On account of this liberal configuration of the separation wall elements, the processing space may in each case be adapted in an optimal manner to the prevailing coating task.

Furthermore, the maximum available size of the processing space around a part-circumference of the lateral face may be utilized in the best possible manner, such that overall greater layer thicknesses may be deposited on the tape substrate than in the case of existing tape-substrate coating line having a comparable process roller diameter.

According to one design embodiment it is provided that the arrangement of compartments has at least one coating compartment in which a coating installation is disposed, wherein each coating compartment is delimited by two separation wall elements, two end wall elements, one external wall element, and one faceplate which faces the process temperature-control roller.

A coating compartment is a space which in relation to the environment is substantially closed and in which a coating installation such as, for example, a single or double magnetron tube having a cylindrical, rotating or stationary, flat (planar) target, or the like, which provides an atomized (vaporous) coating material and dispenses the latter in the direction of the tape substrate which is guided over the lateral face of the process temperature-control roller, is disposed. In other words, the coating compartment is disposed so as to be only slightly spaced above the lateral face of the process temperature-control roller and is open in the direction of the latter, so that the vaporous particles of the coating material may reach the tape substrate.

According to the above design embodiment, the two separation wall elements are complemented by two end wall elements which in relation to the process temperature-control roller extend radially and perpendicularly, that is to say transversely, to the longitudinal axis thereof. These end wall elements moreover may have clearances or openings which provide the required space for a coating installation, for example magnetrons having rotating tubular targets, which is mounted outside the compartment.

Collectively with the end wall elements, the separation wall elements form a frame, the walls (separation wall elements and end wall elements) of which extend radially to the process temperature-control roller. This frame on that side thereof that faces away from the process temperature-control roller is closed by an external wall element. On account thereof, a trough which is open towards the process temperature-control roller is formed. The coating installation is disposed in this trough.

Furthermore, in order for the region, in which vaporous coating material which is dispensed by the coating installation in the direction of the tape substrate which is guided over the lateral face of the process temperature-control roller is dispensed, to be delimited, a faceplate is disposed on that side of the trough that faces the process temperature-control roller. This faceplate in turn may be composed of a plurality of elements, as will be explained in more detail hereunder with reference to the exemplary embodiment.

This design embodiment is exemplary in order for parasitic coating of the interior of the vacuum chamber with coating material to be prevented. Here, the separation wall elements delimit the coating compartment in the peripheral direction, i.e. in the circumferential direction of the lateral face of the process temperature-control roller. The end wall elements delimit the coating compartment in the direction of the longitudinal axis of the process temperature-control roller. The external wall elements delimit the compartment outwardly in the radial direction of the process temperature-control roller, i.e. towards a chamber wall. The faceplate is provided in order to keep the region of the coating compartment clear in the radial direction towards the process temperature-control roller. Therefore, the faceplate has an opening through which the coating material may be deposited from the compartment out onto the tape substrate, wherein that region of the lateral face of the process temperature-control roller above which no tape substrate is disposed is protected by the faceplate against parasitic coating.

In general, this faceplate, as also that of the end wall elements facing the process temperature-control roller, will be cooled, so as to eliminate or at least limit length variations and deformations on account of the application of energy which accompanies the coating. For cooling, these elements of the faceplates are either pressed in a suitable manner against a profile which is perfused by coolant, and may thus be exchanged without releasing water-perfused screw connections, or else the faceplates per se accommodate coolant-perfused ducts which enable increased cooling performance.

According to one further design embodiment, it is provided that at least two coating compartments are formed, and between two adjacent coating compartments at least one segment forms a pumping compartment for vacuum separation between the coating compartments.

In other words, it may be provided that adjacent coating compartments in the peripheral direction of the process temperature-control roller have a mutual spacing and that this spacing, i.e. the space between the two coating compartments, forms a further compartment. This compartment may comprise one or a plurality of segments.

With the proviso that each segment is evacuatable by a vacuum connector, such an additional compartment which is disposed between two coating compartments acts as a pure pumping compartment in which no coating takes place. Evacuating the space between the two coating compartments serves for mutually isolating the processing atmospheres of the two coating compartments so that it is prevented that coating material and process gases may migrate from the one coating compartment into the other coating compartment. This is of particular significance in that different coating materials are deposited in the two adjacent coating compartments and with a view to the respective layer to be deposited on the tape substrate in one coating compartment not being contaminated by the respective other processing atmosphere of another coating compartment.

In contrast to known tape-substrate coating lines it is advantageous in the case of this design embodiment here that both the number of pumping compartments as well as the position thereof within the processing space is flexible and may also be modified after production of the tape-substrate coating line has been carried out. In other words, coating compartments and pumping compartments may be disposed in a denser and more flexible manner within the processing space.

According to one further design embodiment, it is provided that the processing space is subdivided into identically sized segments by the predefined positions of the separation wall elements.

On account thereof, two separation wall elements may be disposed such that by way of the arrangement of one separation wall element each at the adjacent position of an individual segment in the circumferential direction of the process temperature-control roller a coating compartment is so large that a single magnetron tube may be disposed therein as a coating installation, for example. For another coating task it would be simply possible for one of the two separation wall elements to be displaced about one segment in the circumferential direction, such that the enclosed coating compartment comprises two segments. In this compartment a double magnetron tube could be disposed as a coating installation, for example.

The advantage achieved thereby primarily lies in that a largest possible number of different compartment sizes and thus a largest possible number of different line configurations are capable of being displayed using a manageable number of different parts. In any case, the separation wall elements may be embodied in an identical manner, independently of the position at which the former are to be disposed in relation to the process temperature-control roller, i.e. each separation wall element may be attached to any arbitrary position.

By contrast, the size of the external wall elements and of the faceplates depends on how many segments are to be covered by one coating compartment, and on how large each of these segments is. However, when the individual segments are of identical size, then the sizes of the faceplates and of the external wall segments depend only on the number of the covered segments, i.e. an external wall element which covers one segment may also be attached to any other segment; an external wall element which covers two segments may also be attached to any other pair of segments, etc. The same applies to the faceplates.

According to one further design embodiment, it is provided that at least one vacuum connector for connecting a vacuum pump is disposed in the region of each segment.

This compartment may be evacuated in this way independently of how many segments are used to form one compartment and of where the compartment is disposed on the lateral face of the process temperature-control roller. In other words, a higher pump performance is also available for compartments which comprise a plurality of segments. It may also be provided for a plurality of vacuum connectors to be disposed along the longitudinal axis of the process temperature-control roller in the region of one segment, for example, this being particularly advantageous for tape substrates having large dimensions in the direction of the longitudinal axis of the process temperature-control roller.

This design embodiment offers maximum flexibility in terms of evacuating the entire processing space, since each individual segment is evacuatable separately. However, it is of course possible here to dispense with the evacuation of individual segments, for example in that the associated vacuum connectors are not connected to a vacuum pump but are closed using blank covers. For example, when one coating compartment covers three segments, it may be sufficient in some instances for only one of the three associated vacuum connectors to be connected to one vacuum pump and for the other two vacuum connectors to be closed.

According to one further design embodiment, it is provided that the vacuum connectors on one chamber wall are disposed such that vacuum pumps which are attached to the latter have direct pumping access to the respectively associated segment.

In this way, the volume to be evacuated is further minimized, since the vacuum pumps are disposed in the immediate proximity of the respective segment, outside the vacuum chamber.

In other words, the chamber wall and thus also the vacuum connectors which are disposed thereon are disposed so as to be so close to the segments that the vacuum pumps have an immediate evacuating effect on the segment. This may be achieved, for example, in that the chamber wall per se at least in regions has a cylindrical shape, such that said chamber wall, having the spacing required for the compartments, follows the contour of the process temperature-control roller. The chamber wall may have a trough-like shape, for example.

According to one further design embodiment, it is provided that all faceplates are releasably fastened to a common mounting installation and by way of the common mounting installation are held in a secured relative position in relation to the process temperature-control roller.

The common mounting installation may comprise two plates, for example, each being disposed at one end of the process temperature-control roller, such that each faceplate by way of each of the two end-face ends thereof is attached to one of the two plates. On account thereof, the two plates and the faceplates form a basket, so to speak, which encompasses the process temperature-control roller.

According to one further design embodiment, it is provided that the positions of the faceplates on the common mounting installation are adjustable in relation to the process temperature-control roller.

Like the separation wall elements, the faceplates are also attachable in different positions in the peripheral direction across the circumference of the process temperature-control roller. Moreover, however, according to this design embodiment, the faceplates are also adjustable in terms of the radial spacing thereof from the process temperature-control roller, that is to say that the radial spacing of said faceplates is variable, depending on which specific requirements are required for a specific coating step. This adjustability may be implemented, for example, in that the common mounting installation has elongate holes in which the faceplates are attachable in different positions, for example by means of screws.

This is advantageous for adjusting the spacing of a faceplate from the lateral face of the process temperature-control roller, for example. The flow resistance between two adjacent compartments is also determined by way of the spacing of the faceplate from the lateral face of the process temperature-control roller. The flow resistance is also adjustable and capable of maximization by way of the adjustability of this spacing. On account thereof, the tape-substrate coating line is adaptable in a flexible manner to different thicknesses of the tape substrate, wherein the thickness of the tape substrate represent that dimension of the tape substrate that extends in the radial direction to the process temperature-control roller.

According to one further design embodiment, it is provided that the external wall element, so as to correspond with the number of the covered segments, has a number of openings each being disposed over a vacuum connector.

It is ensured in this way that the interior of a coating compartment is evacuatable through all available vacuum connectors of the segments of that compartment, wherein the interior of the chamber wall is likewise protected by the external wall element against parasitic coating of the coating installation.

As has already been described above, the external wall elements primarily serve for delimiting the coating compartment in relation to the immediate environment, that is to say the interior of the vacuum chamber, so as to prevent any gas exchange between the coating compartment and the vacuum chamber. In order for the coating compartment to nevertheless be capable of evacuation it is necessary to enable the vacuum pump or pumps pumping access to the coating compartment. This is achieved in that the external wall elements of the coating compartment in the region of each vacuum connector have an opening through which the coating compartment may be evacuated.

According to one further design embodiment, it is provided that the external wall elements of the coating compartments are disposed in a locationally fixed manner on a chamber wall of the vacuum chamber.

This design embodiment is particularly meaningful when the various wall elements which delimit one coating compartment are to be movable in relation to one another. This may be desirable in particular in order to achieve that individual elements of the tape-substrate coating line are readily accessible for maintenance purposes and that said elements may be assembled and dismantled on demand in a simple manner.

According to one further design embodiment, it is provided that the separation wall elements of each coating compartment contact in a linear manner the associated faceplate and the associated external wall element.

Contact in a linear manner here is to be understood that two mutually contacting elements, such as a separation wall element and a faceplate, or a separation wall element and an external wall element, are assembled such that a gas exchange between the interior of the coating compartment and the vacuum chamber, i.e. through the joint, is reduced to a minimum, i.e. is largely impeded.

In other words, the interior of the coating compartment in relation to the vacuum chamber is to be sealed at the joints of mutually contacting elements. Linear here is to be understood merely as a direction, for example in the axial direction of the process temperature-control roller, but not as being limiting in terms of the size of the contact face. The region in which the elements are in mutual contact may rather also be configured as a planar area.

According to one further design embodiment, it is provided that of two mutually contacting elements each one of the elements has a groove which runs in the axial direction of the process temperature-control roller and in which the other element is inserted or push-fitted.

On account of this tongue-and-groove design the area of that region in which the two elements are in mutual contact may be enlarged, on account of which a volumetric flow due to leakage through the joint is reduced.

For example, it may be provided that an external wall element on the edges thereof that run parallel with the longitudinal axis of the process temperature-control roller has a groove. A separation wall element may be inserted into this groove such that a gas flow under high-vacuum conditions between the separation wall element and the external wall element can be practically excluded. On account thereof, it is moreover possible for the separation wall element and the external wall element to be assembled in that the separation wall element is push-fitted into the groove so as to be parallel with the longitudinal axis of the process temperature-control roller.

According to one further design embodiment, it is provided that of two mutually contacting elements each one of the elements has a spring steel sheet which runs in the axial direction of the process temperature-control roller and which presses in an elastic manner onto the other contacting element.

It may be provided, for example, that each faceplate on the edges thereof that run parallel with the longitudinal axis of the process temperature-control roller has in each case one spring steel sheet which comes into elastic contact with in each case one separation wall element, such that a gas flow under high-vacuum conditions between the separation wall element and the faceplate can be practically excluded.

According to one further design embodiment, it is provided that all separation wall elements, end wall elements, and coating installations are comprised by a first part-arrangement, and all faceplates and the process temperature-control roller are comprised by a second part-arrangement, wherein the first part-arrangement and the second part-arrangement are mutually convergeable in the axial direction of the process temperature-control roller.

By way of these elements being grouped in part-arrangement, both the configuration as well as the maintenance of the tape-substrate coating line is significantly simplified. This arrangement is advantageous since, on account thereof, accessibility to the coating installations for the purpose of replacing or servicing the same is significantly improved. This is achieved in that the coating compartments by way of the mutual relative mobility of the two part-arrangements are opened up. In other words, access to the interior of the coating compartment is possible on account of the relative mobility of the faceplates and of the process temperature-control roller of the second part-arrangement in relation to the end wall elements, to the separation wall elements, and to the coating installations of the first part-arrangement.

According to one further design embodiment, it is provided that the second part-arrangement comprises the conveying installation.

This is advantageous since, on account thereof, the tape substrate is movable collectively with the process temperature-control roller in relation to the coating installations. Therefore, in order for the second part-arrangement to be moved, the tape substrate may bear on a part-circumference of the lateral face of the process temperature-control roller, dispensing with time-consuming removal of the tape substrate in the case of servicing.

As opposed to design embodiments in which separate reeling chambers are provided for a take-up roll and a supply roll of the tape substrate, in this case the take-up roll and the supply roll are disposed within the vacuum chamber. This means that the tape substrate is movable out of the vacuum chamber together with the second part-arrangement.

According to one further design embodiment, it is provided that the second part-arrangement comprises the common mounting installation of the faceplates.

It is advantageous here that the faceplates are movable collectively with the process temperature-control roller, on account of which the position of the faceplates in relation to the process temperature-control roller is not modified during that movement, such that the spacing of the faceplate from the lateral face of the process temperature-control roller, which determines the flow resistance between two adjacent compartments, remains constant, for example.

According to one further design embodiment, it is provided that that the vacuum chamber has two mutually opposite openings which by way of one removable chamber wall each are closable in a vacuum-tight manner, wherein the two part-arrangements are movable out of the vacuum chamber or into the vacuum chamber through each one of the two openings.

By way of this design embodiment it is achieved that the two part-arrangements are independently movable out of the vacuum chamber and thereinto again, wherein accessibility to the coating installations is moreover improved. Each of the part-arrangements here may be disposed on one rail-guided carriage each. On account thereof, it is particularly simple for the components of the device for substrate treatment to be removed from the vacuum chamber, for example for maintenance purposes.

According to one further design embodiment, it is provided that each part-arrangement is attached to one of the two removable chamber walls and, on account thereof, upon removal of the respective chamber wall, is removed from the vacuum chamber.

On account thereof, it is achieved that no further device has to be provided in order for the two chamber walls to be removed. Moreover, this design embodiment has the advantage that the part-arrangements which are attached to the chamber walls are attachable with high precision to the positions specified for the former within the vacuum chamber. At the same time, the part-arrangements may be removed in the simplest manner from the vacuum chamber in that the chamber walls are released and removed from the vacuum chamber, for example in that the removable chamber walls are mounted on a rail system and are displaceable thereon.

According to one further design embodiment, it is provided that an evacuatable treatment space which extends across a further part-circumference of the lateral face is disposed outside the processing space.

This is advantageous since, on account thereof, the treatment space by means of dedicated vacuum pumps which are disposed outside the vacuum chamber is evacuatable independently of the vacuum chamber and independently of the compartments.

It may be further provided here that at least one treatment installation for pre-treating and/or post-treating the tape substrate is disposed in the treatment space.

The treatment space thus differs from the processing space in that no coating of the tape substrate takes place in the treatment space. Rather, treatment installations such as, for example, a plasma source, or a glow installation, by way of which the tape substrate may be purified, de-gassed, surface-activated, heated, or cooled, for example, may be disposed in the treatment space.

According to one further design embodiment, it is provided that the conveying installation is configured for bi-directional conveyance of the tape substrate.

On account thereof, it becomes possible for the tape-substrate coating line to be selectively operated in one direction or another, or for the tape-substrate coating line to be operated both in one as well as the other direction.

On account thereof, it may be achieved that the arrangement of the take-up roll and the supply roll do not have to be replaced prior to renewed coating of the tape substrate, and renewed threading of the tape substrate along the process temperature-control roller may be dispensed with, on account of which venting the reeling chambers or the vacuum chamber may likewise be dispensed with.

In terms of bi-directional conveyance of the tape substrate it is furthermore advantageous for at least two treatment spaces to be provided. These may be configured so as to be evacuatable in a mutually independent manner. A treatment installation for pre and/or post treatment of the tape substrate may be present in each of the two treatment spaces, on account of which both pre-treatment as well as post-treatment of the tape substrate independently of the conveying direction of the tape substrate is possible.

It is furthermore possible that a winding space which is provided with dedicated vacuum pumps and which is configured by flow resistances, embodied as gaps through which the substrate runs, is configured outside the processing and treatment space. On account thereof, it is possible for perspiration and evaporation from the substrate roll, which escape during unwinding of the substrate, to be effectively kept away from the process and treatment space.

### BRIEF DESCRIPTION OF THE DRAWING FIGURES

The invention will be explained in more detail hereunder by means of an exemplary embodiment and of associated drawings. In the drawings:

FIG. 1 shows a vacuum chamber having the external wall elements, a tape carriage, and a process carriage of a tape-substrate coating line, in the open position;

FIG. 2 shows the external wall elements and the first part-arrangement as well as the second part-arrangement;

FIG. 3 shows a sectional view of the vacuum chamber, perpendicular to the central axis of the process temperature-control roller, having a first exemplary arrangement of coating installations;

FIG. 4 shows an assembly drawing of a faceplate;

FIG. 5 shows an exploded drawing of the faceplate according to FIG. 4; and

FIG. 6 shows a side view of an end wall element.

FIG. 7 shows a sectional view of the vacuum chamber, perpendicular to the central axis of the process temperature-control roller, having a second exemplary arrangement of coating installations; and

FIG. 8 shows a sectional view of the vacuum chamber, perpendicular to the central axis of the process temperature-control roller, having a third exemplary arrangement of coating installations.

### DETAILED DESCRIPTION

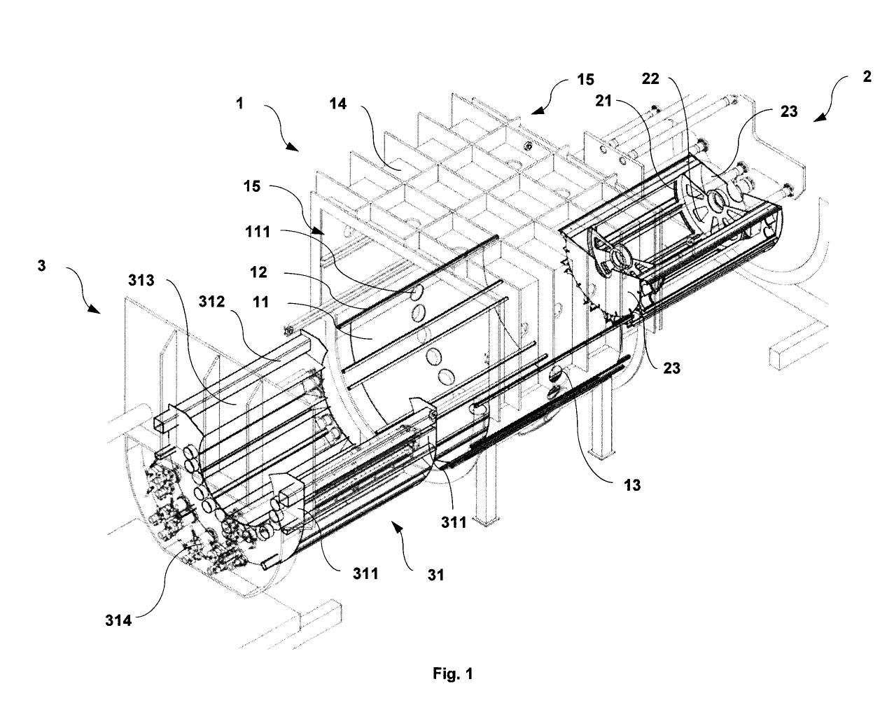

FIG. 1 shows a tape-substrate coating line comprising a locationally fixed vacuum chamber 1, a movable tape carriage 2, and a process carriage 3 which is movable in relation to the tape carriage 2. The evacuatable vacuum chamber 1 which is formed by chamber walls 14 has two mutually opposed openings 15 which are closable in a vacuum-tight manner. Both the tape carriage 2 as well as the process carriage 3 are movable by way of rails (not illustrated) into the vacuum chamber 1 and out therefrom through in each case one opening 15. Both the tape carriage 2 as well as the process carriage 3 furthermore each comprise one chamber wall 14 by way of which each one of the mutually opposite openings 15 of the vacuum chamber 1 is closable in a vacuum-tight manner.

The tape carriage 2 comprises a conveying installation for conveying a tape substrate (not illustrated) from a supply roll (not illustrated) towards the process temperature-control roller 22, guiding the tape substrate along a part-circumference of the process temperature-control roller 22, and conveying the tape substrate to a take-up roll (not illustrated). FIG. 1 merely shows deflection rollers (not referred to in more detail) of the conveying installation.

The tape carriage 2 furthermore comprises a mounting installation 23 on which a plurality of faceplates 21 are disposed. The spacing of the faceplates 21 from the process temperature-control roller 22 is adjustable, depending on the process.

The tape substrate which is guided along the process temperature-control roller 22 may be both cooled as well as heated by means of the process temperature-control roller 22, wherein the process temperature-control roller 22 is rotatable about the central axis thereof by means of a drive (not illustrated) which is disposed outside the vacuum chamber 1.

Therefore, the process temperature-control roller 22, the mounting installation 23 having the faceplates 21 disposed thereon, and the conveying installation form a second part-arrangement which by means of the tape carriage 2 is movable out of the vacuum chamber 1 and back therein. Once the spacing between the faceplates 21 and the process temperature-control roller 22 has been adjusted, said spacing is not influenced by the mutual relative movement between the tape carriage 2 and the process carriage 3.

A mounting installation 31 is disposed on the process carriage 3. This mounting installation 31 is formed by transverse supports 312 which are formed from tubular profiles, for example, and by two end wall elements 311 which are configured as sheet metal panels, for example. The transverse supports 312 and the end wall elements 311 form a flexurally resistant arrangement. The two end wall elements 311 furthermore are configured such that they each delimit the processing space at one end side.

The mounting installation 31 furthermore comprises separation wall elements 313 which are releasably disposed on the former, such that the separation wall elements 313 may be cleaned remotely from the process carriage 3.

Moreover, a plurality of coating installations 314 are disposed on the mounting installation 31. In this exemplary embodiment the coating installations 314 are configured as double magnetron tubes and single magnetron tubes. However, other coating installations 314, such as for example, planar magnetrons, thermal evaporators having steam manifold tubes, ion sources, or else other coating sources may be provided. The coating installations 314 in the present exemplary embodiment are held in a coating installation opening 3111 in one of the two end wall elements 311.

Therefore, the mounting installation 31 having the separation wall elements 313 and coating installations 314 arranged thereon forms a first part-arrangement which by means of the process carriage 3 is movable out of the vacuum chamber 1 and back therein.

A plurality of mounting elements 12, the longitudinal extent of which is aligned so as to be parallel with the central axis of the process temperature-control roller 22, are disposed in the interior of the vacuum chamber 1. The mounting elements 12 may be disposed on the most varied positions within the vacuum chamber 1. Each external wall element 11 is held by two adjacent mounting elements 12. At least one opening 111 is provided in each external wall element 11. Each opening 111 of an external wall element 11 is disposed above a vacuum connector 13 of a chamber wall 14. A vacuum pump (not illustrated) which is connectable to a vacuum connector 13 thus has direct pumping access to the interior of a processing space.

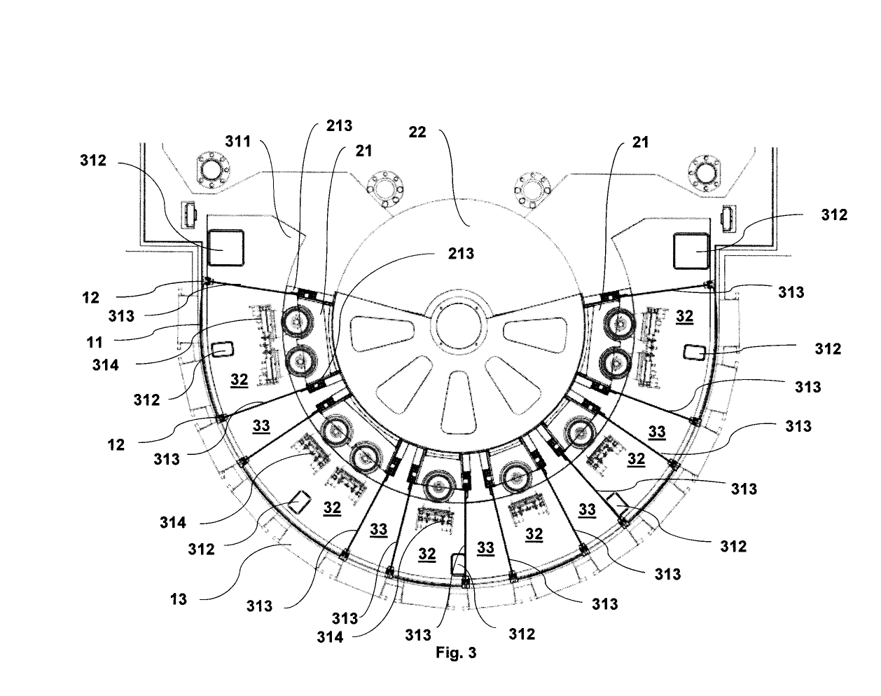

The configuration of this processing space is to be described in more detail by means of FIG. 3. To this end, FIG. 3 shows a sectional view of the vacuum chamber 1, perpendicular to the central axis of the process temperature-control roller 22.

The processing space encloses a part-circumference of the lateral face of the process temperature-control roller 22 in a toroidal manner. In this exemplary embodiment this part-circumference is approx. 180°, wherein this part-circumference in another design embodiment of the tape-substrate coating line may also be chosen to be larger or smaller. The processing space is formed by coating compartments 32 and pumping compartments 33 which are disposed alternately in the conveying direction of the tape substrate, wherein the pumping compartments 33 are provided for vacuum separation and thus for gas separation between the coating compartments 32.

This exemplary embodiment comprises six coating compartments 32, wherein three coating compartments 32 are configured such that a coating installation 314 in the form of a double magnetron tube may be disposed therein, and wherein three further coating compartments 32 are configured such that a coating installation 314 in the form of a single magnetron tube may be disposed therein.

Each of the coating compartments 32 here is formed by two separation wall elements 313, one external wall element 11, one faceplate 21 facing the process temperature-control roller, and two mutually opposite end wall elements 311. The faceplates 21 as well as the external wall elements 11 for the coating compartments of dissimilar size have dissimilar sizes in the circumferential direction of the lateral face of the process temperature-control roller 22. Each of the coating compartments 32 may be separately evacuated by means of one or a plurality of vacuum pump(s) which is/are disposed outside the vacuum chamber 1. To this end, a corresponding number of openings 111 are provided in the respective external wall elements, which openings 111 in turn are disposed above a vacuum connector 13 of the chamber wall 14. In this way, a vacuum pump (not illustrated) which is disposed on the vacuum connector 13 may obtain direct pumping access to the interior of the coating compartment 32.

Each pumping compartment 33 is formed by the separation wall elements 313 of two adjacent coating compartments 32. No external wall element 11 and no faceplate 21 are provided for a pumping compartment 33. A vacuum connector 13 is likewise assigned to each pumping compartment, on account of which a vacuum pump (not illustrated) obtains direct pumping access to the interior of the pumping compartment 33, on account of which gas separation may be achieved between two adjacent coating compartments 32.

In order to get from the open position of the tape-substrate coating line to the closed position, preferably the first part-arrangement is initially moved by means of the process carriage 3 into the vacuum chamber 1. Here, the separation elements 313 are pushed in grooves of the mounting elements 12 that are aligned so as to be parallel with the central axis of the process temperature-control roller 22. Subsequently, the second part-arrangement is moved by means of the tape carriage 2 into the vacuum chamber 1. Here, in each case one spring steel sheet 213 of the faceplate 21 bears on one separation wall element 313 of the first part-arrangement. The in each case linear region of contact between a separation wall element 313 having a mounting element 12 and a spring steel sheet 213 here is configured such that a volume flow on account of a pressure differential between the vacuum chamber 1 and the interior of a coating compartment 32 is reduced to a minimum. A sealing effect of the linear contact should be as high as possible.

The concept of the invention lies in that the size, number and arrangement of the compartments 32, 33 are variable. In order for this to be achieved, the separation wall elements 313 may be disposed at various pre-defined positions of the processing space. This is to be explained in more detail by means of the coating compartment 32 which is located at the 9 o'clock position. For example, if a single magnetron tube is to be disposed in this coating compartment 32, the size of the latter may be much smaller so as to reduce the pump performance of the vacuum pump required for this coating compartment 32. To this end, the mounting element 12 which is illustrated as being therebelow is released from the chamber wall 14 of the vacuum chamber 1 and is again fastened to the chamber wall 14 at a position between two adjacent vacuum connectors 13, so as to be closer to the mounting element 12 which is illustrated as being thereabove. Moreover, that separation wall element 313 on the first part-arrangement that is assigned to this mounting element 12 is displaced, so that this separation wall element 313 may again be introduced into the groove of the mounting element 12. On the second part-arrangement, the faceplate 21 has to be exchanged for a faceplate 21 which is smaller in the circumferential direction of the process temperature-control roller 22. In this case, the external wall element 11 has likewise to be replaced by a smaller external wall element.

It is advantageous when the mounting elements 12 each may be disposed at regular spacing between two vacuum connectors 13. In this way it is possible for the processing space to be subdivided into segments of identical size. There are thus fourteen segments in the case of the present exemplary embodiment. The coating compartments 32 of an exemplary embodiment may thus comprise one or a plurality of segments, for example four or six segments. On account thereof, coating tasks of the same type, for example coating the tape substrate with one and the same coating material, may be grouped together. By assigning one vacuum connector 13 to each segment, the pump performance is likewise conjointly increased when coating compartments are enlarged.

It is essential that the modification of the size, number and arrangement of the compartments 32, 33 may also be carried out post production of the tape-substrate coating line, on account of which the reaction to, for example, novel layer systems may be very flexible, without a tape-substrate coating line which has been specially adapted to this novel layer system having to be acquired.

In the case of the present exemplary embodiment it may furthermore be provided that at least one evacuatable treatment space (not illustrated) is disposed above the two coating compartments 32 at the 3 o'clock position and the 9 o'clock position according to FIG. 3, and thus outside the processing space, so as to be along a part-circumference of the lateral face of the process temperature-control roller 22. In this treatment space, which is evacuatable by means of vacuum pumps which are disposed outside the vacuum chamber 1, in turn treatment installations for pre and/or post treatment of the tape substrate may be disposed. On account thereof, the circumference of the process temperature-control roller 22 is utilized in an optimum manner by devices for surface treatment, either for pre treatment, coating, or post treatment of the tape substrate. It may moreover be provided that two treatment spaces which have devices for both pre and post treatment of the tape substrate are disposed in the vacuum chamber 1. In this way it is also possible for a conveying installation for bi-directional operation of the tape substrate to be provided. Upon reversal of the conveying direction it is thus ensured that the tape substrate may then be both pre-treated as well as post-treated. It is also possible for the tape substrate to be subjected to merely pre treatment or to post treatment.

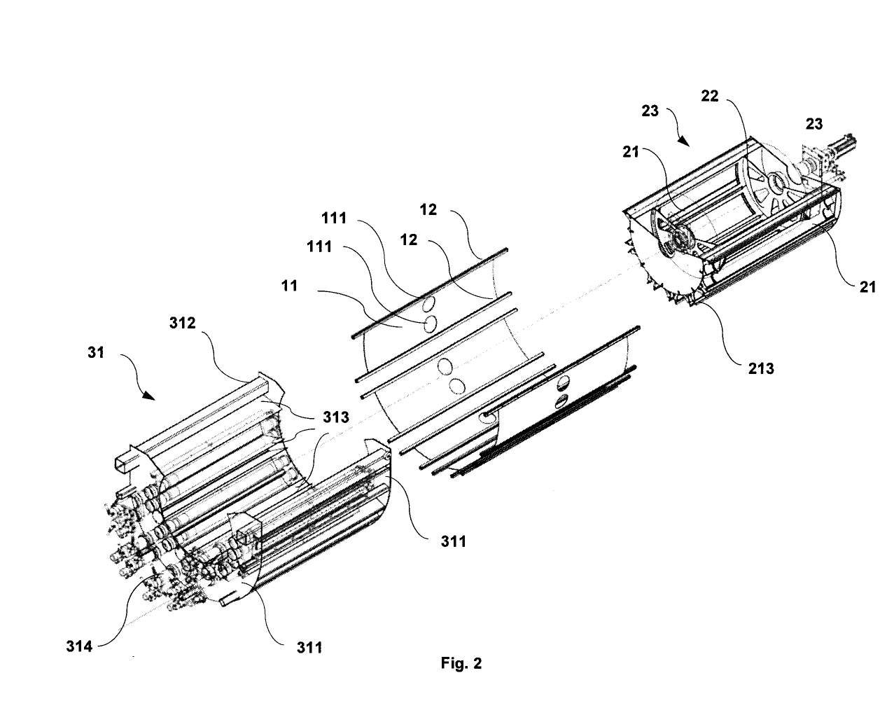

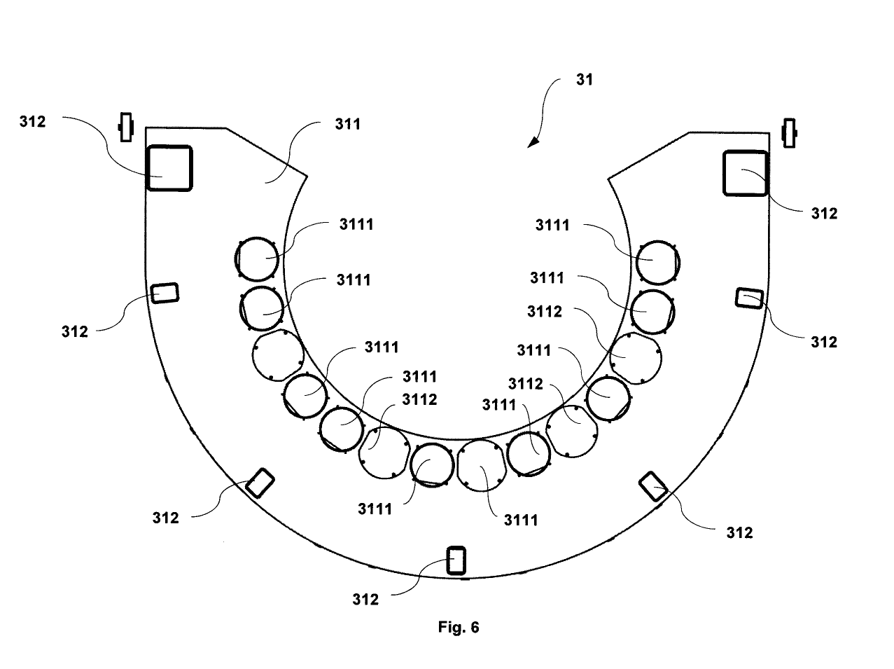

The mounting installation 31 of the process carriage 3, which is illustrated in FIG. 6, is configured so as to correspond to the configuration of the processing space of FIGS. 1 to 3. The coating installations 314 (not illustrated here) are disposed in the coating installation openings 3111, whereas these coating installation openings 3111 in the region of the pumping compartment 33 are each closed by a closure 3112, so as to avoid flows due to leakage.

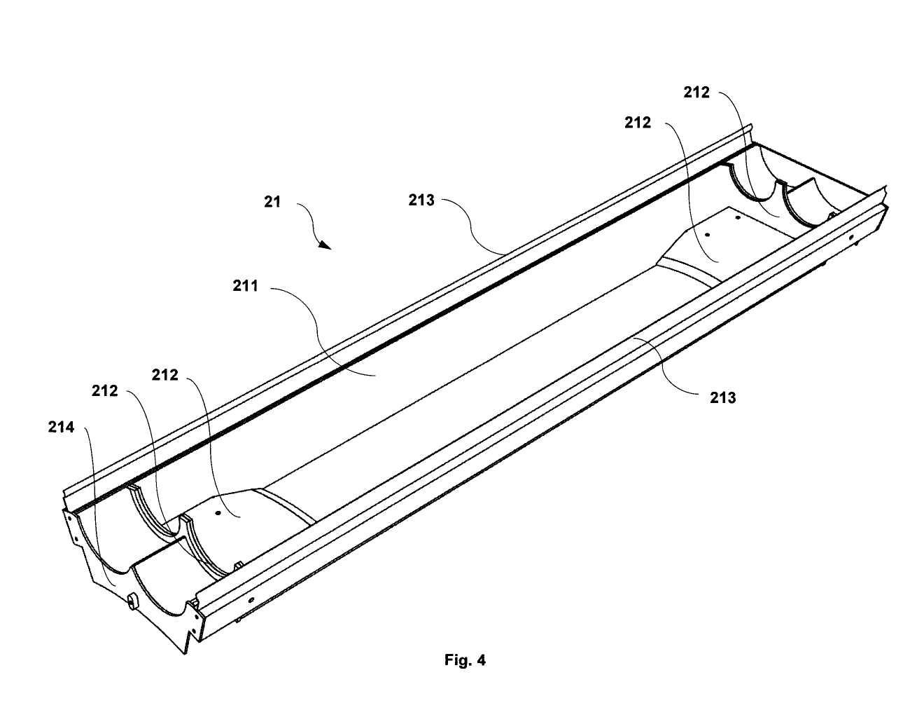

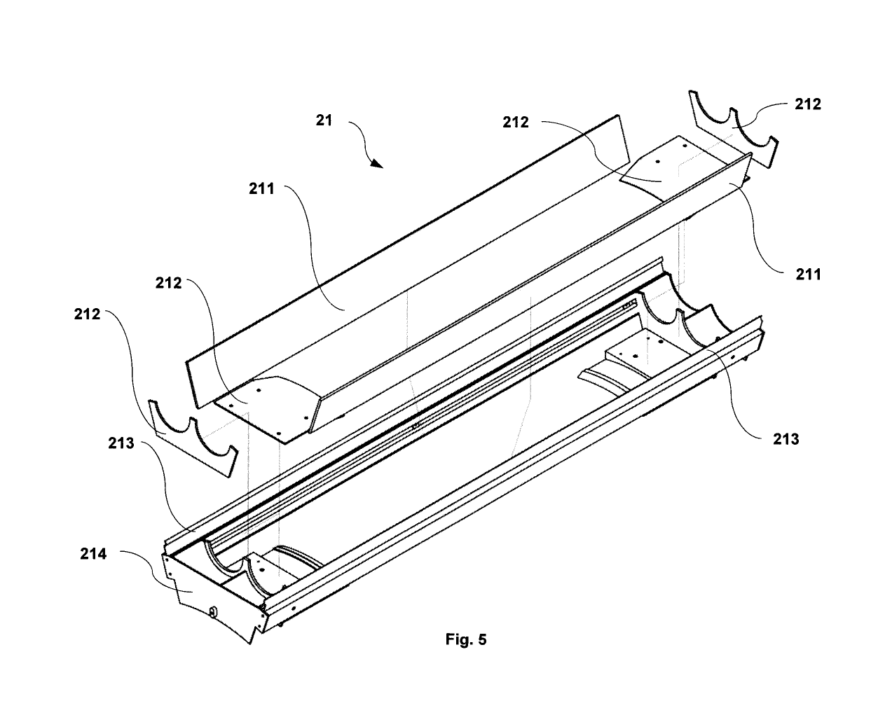

FIGS. 4 and 5 show the construction of one and the same faceplate 21 for a double magnetron tube. The illustrated faceplate 21 comprises a main support 214 having spring steel sheets 213 fastened thereto, which are capable of being brought into contact with the separation wall elements 313. As a protection against parasitic coating of the main support, in each case two longitudinal guards 211 and in each case four end guards 212 are interchangeably disposed on said main support, for example by means of a screw connection. It may be furthermore provided that cooling ducts (likewise not illustrated) for cooling the faceplate 21, as well as for gas ducts (not illustrated) are disposed, wherein the gas ducts are suitable for making available process gas, for example a reactive gas, for specific coating installations.

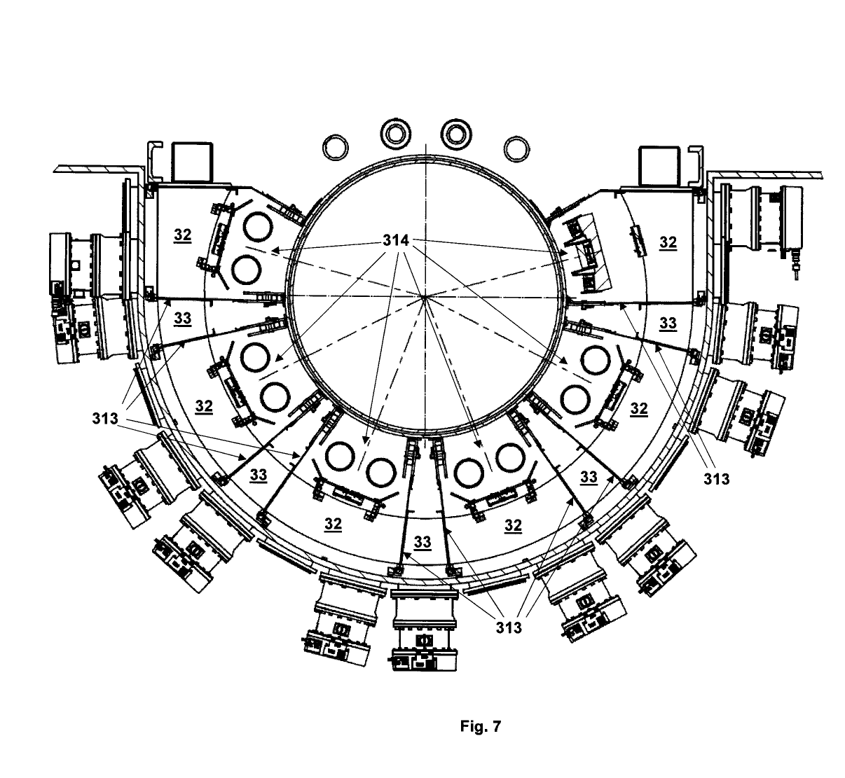

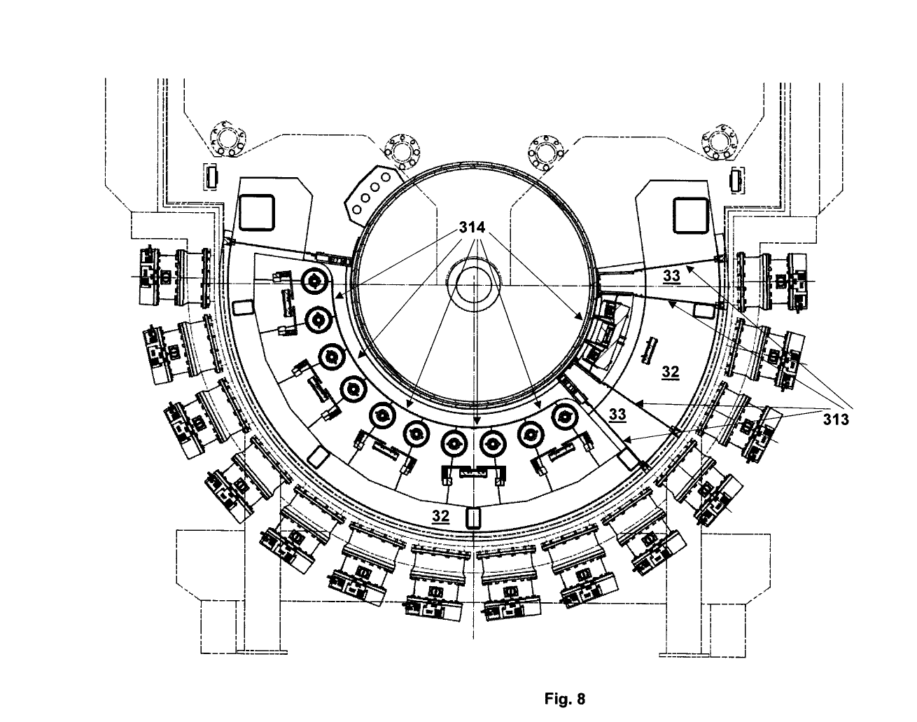

FIGS. 7 and 8 show two further exemplary configurations of coating installations which by the variable division according to the invention of the processing space which partially encloses the process temperature-control roller.

As in the case of the configuration shown in FIG. 3, this processing space is subdivided by a plurality of 313 into coating compartments 32 and pumping compartments 33, wherein one or a plurality of coating installations 314 are disposed in each coating compartment 32.

In the case of the exemplary embodiment according to FIG. 7 a total of six coating compartments 32 and one pumping compartment 33 each is disposed between each two coating compartments 32. Here, when viewed in the conveying direction of the substrate, in each case one double magnetron tube 314 is disposed in the first five coating compartments 32 and one planar magnetron is disposed in the last coating compartment 32. Each coating compartment 32 and each pumping compartment 33 is evacuated by one externally attached vacuum pump each.

In the case of the exemplary embodiment according to FIG. 8 a total of two coating compartments 32 and two pumping compartments 33 are alternatingly disposed, wherein when viewed in the conveying direction of the substrate, five double magnetron tubes 314 are disposed in the first coating compartment 32 and one planar magnetron is disposed in the second coating compartment 32. Vacuum pumps are disposed on all vacuum connectors 13 present.

1. A tape-substrate coating line having a vacuum chamber formed by chamber walls and a device, disposed in the vacuum chamber, for surface treatment of a tape substrate, and comprising a process temperature-control roller having a cylindrical lateral face, wherein at least one part-circumference of the lateral face is enclosed by a processing space which has an arrangement of compartments delimited by separation wall elements, wherein at least one coating installation is disposed in at least one compartment, and comprising a conveying installation for conveying the tape substrate over the lateral face, wherein size, number and arrangement of the compartments are variable in that each separation wall element is attachable to one of a plurality of predefined positions within the processing space.

2. The tape-substrate coating line according to claim 1, wherein the arrangement of compartments has at least one coating compartment in which a coating installation is disposed, wherein each coating compartment is delimited by two separation wall elements, two end wall elements, one external wall element, and one faceplate which faces the process temperature-control roller.

3. The tape-substrate coating line according to claim 2, including at least two coating compartments, and between two adjacent coating compartments at least one segment forms a pumping compartment for vacuum separation between the coating compartments.

4. The tape-substrate coating line according to claim 1, wherein the processing space is subdivided into identically sized segments by the plurality of predefined positions.

5. The tape-substrate coating line according to claim 3, wherein at least one vacuum connector for connecting a vacuum pump is disposed in a region of each segment.

6. The tape-substrate coating line according to claim 5, wherein vacuum connectors on one chamber wall are disposed such that vacuum pumps which are attached to the latter have direct pumping access to a respectively associated segment.

7. The tape-substrate coating line according to claim 2, wherein all faceplates are releasably fastened to a common mounting installation and by way of the common mounting installation are held in a secured relative position in relation to the process temperature-control roller.

8. The tape-substrate coating line according to claim 7, wherein positions of the faceplates on the common mounting installation are adjustable in relation to the process temperature-control roller.

9. The tape-substrate coating line according to claim 5, wherein the external wall element, so as to correspond with the number of the covered segments, has a number of openings which each are disposed over a vacuum connector.

10. The tape-substrate coating line according to claim 2, wherein the external wall elements of the coating compartments are disposed in a locationally fixed manner on a chamber wall of the vacuum chamber.

11. The tape-substrate coating line according to claim 2, wherein the separation wall elements of each coating compartment contact in a linear manner the associated faceplate and an associated external wall element.

12. The tape-substrate coating line according to claim 11, wherein, in each case, of two mutually contacting elements, one of the elements has a groove which runs in an axial direction of the process temperature-control roller in which another element is inserted or push-fitted.

13. The tape-substrate coating line according to claim 11, wherein, in each case, of two mutually contacting elements, one of the elements has a spring steel sheet which runs in an axial direction of the process temperature-control roller and which presses in an elastic manner onto another contacting element.

14. The tape-substrate coating line according to claim 2, wherein all separation wall elements, end wall elements, and coating installations are comprised by a first part-arrangement, and all faceplates and the process temperature-control roller are comprised by a second part-arrangement, wherein the first part-arrangement and the second part-arrangement are mutually convergeable in an axial direction of the process temperature-control roller.

15. The tape-substrate coating line according to claim 14, wherein the second part-arrangement comprises the conveying installation.

16. The tape-substrate coating line according to claim 14, wherein the second part-arrangement comprises a common mounting installation of the faceplates.

17. The tape-substrate coating line according to claim 14, wherein the vacuum chamber has two mutually opposite openings each, by way of one removable chamber wall, being closable in a vacuum-tight manner, wherein the two part-arrangement is movable out of the vacuum chamber or into the vacuum chamber through one of the two openings.

18. The tape-substrate coating line according to claim 17, wherein each part-arrangement is attached to one of the two removable chamber walls and, on account thereof, upon removal of the respective chamber wall, is removed from the vacuum chamber.

19. The tape-substrate coating line according to claim 1, wherein an evacuatable treatment space which extends across a further part-circumference of the lateral face is disposed outside the processing space.

20. The tape-substrate coating line according to claim 19, wherein at least one treatment installation for pre-treating and/or post-treating the tape substrate is disposed in the treatment space.

21. The tape-substrate coating line according to claim 1, wherein the conveying installation is configured for bi-directional conveyance of the tape substrate.

22. The tape-substrate coating line according to claim 1, wherein at least one first substrate reel for providing a substrate to be coated and at least one second substrate reel for taking up the substrate are provided, and at least one substrate reel is disposed in a reeling space which is separated from the vacuum chamber by flow resistances and is separately evacuatable.
